(19) United States
(12) Patent Application Publication
(10) Pub. No.: US 2026/0333912 A1
(43) Pub. Date: Oct. 22, 2026

(54) IMAGE SENSOR

(71) Applicant: VisEra Technologies Company Ltd., Hsin-Chu City (TW)

(72) Inventors: Wen-Yu SHIH, Hsin-Chu City (TW); Po-Han FU, Hsin-Chu City (TW); Chin-Chuan HSIEH, Hsin-Chu City (TW)

(21) Appl. No.: 19/182,822

(22) Filed: Apr. 18, 2025

(51) Int. Cl. H10F 39/00; G02B 1/00

(52) U.S. Cl. CPC H10F 39/806; G02B 1/002; H10F 39/024; H10F 39/8053

(57) ABSTRACT

An image sensor includes a substrate, a color filter layer, a first spacer layer, a first protection layer, a first metasurface layer, a second spacer layer, and a second protection layer. The color filter layer is on the substrate. The first spacer layer is on the substrate and covers the color filter layer. The first protection layer covers the first spacer layer. The first metasurface layer is above the first protection layer. The second spacer layer is on the first protection layer and covers the first metasurface layer. The second protection layer covers the second spacer layer. An elastic modulus ratio of the first protection layer to the first spacer layer is in a range from 30 to 200, and an elastic modulus ratio of the second protection layer to the second spacer layer is in a range from 30 to 200.

### BACKGROUND

### Field of Invention

The present disclosure relates to an image sensor. More particularly, the present disclosure relates to the image sensor having specific elastic modulus ratios and thickness ratios between different layers in the image sensor.

### Description of Related Art

In the field of complementary metal oxide semiconductor (CMOS) image sensors (also referred to as CIS), a color router is used to direct or distribute light based on its wavelength color and could be applied in optical communication, imaging systems, and so on. The color router may be formed by a plurality of layers with different materials. However, different layers with different materials may cause mismatches when manufacturing the color router, resulting in stress issues, such as peeling or cracking. Therefore, there is a need to solve the above problems.

### SUMMARY

The image sensors of the present disclosure have specific elastic modulus ratios and thickness ratios between different layers, which can optimize the stress between different layers in the image sensors to avoid failure (such as peeling or cracking), thereby increasing the image sensors' performance.

One aspect of the present disclosure is to provide an image sensor including a substrate, a color filter layer, a first spacer layer, a first protection layer, a first metasurface layer, a second spacer layer, and a second protection layer. The color filter layer is disposed on the substrate. The first spacer layer is disposed on the substrate and covers the color filter layer. The first protection layer covers the first spacer layer. The first metasurface layer is disposed above the first protection layer. The second spacer layer is disposed on the first protection layer and covers the first metasurface layer. The second protection layer covers the second spacer layer. An elastic modulus ratio of the first protection layer to the first spacer layer is in a range from 30 to 200, an elastic modulus ratio of the second protection layer to the second spacer layer is in a range from 30 to 200, a thickness ratio of the first protection layer to the first spacer layer is in a range from 0.05 to 1, and a thickness ratio of the second protection layer to the second spacer layer is in a range from 0.05 to 1.

According to some embodiments of the present disclosure, the substrate includes an active area and a periphery area adjacent to the active area, the active area includes a plurality of pixels, the color filter layer is disposed on the pixels, and the first spacer layer covers the active area and the periphery area.

According to some embodiments of the present disclosure, the first spacer layer has a first inclined sidewall above the periphery area, and the second spacer layer has a second inclined sidewall above the periphery area. A horizontal distance between a bottommost end of the first inclined sidewall and an edge of the color filter layer is greater than a horizontal distance between a bottommost end of the second inclined sidewall and the edge of the color filter layer.

According to some embodiments of the present disclosure, the first protection layer has a first horizontal portion and a first inclined portion connecting the first horizontal portion and covering the first inclined sidewall. The second protection layer has a second horizontal portion and a second inclined portion connecting the second horizontal portion and covering the second inclined sidewall. The second inclined portion contacts the first horizontal portion such that the image sensor has a continuous oblique surface.

According to some embodiments of the present disclosure, a horizontal distance between the bottommost end of the second inclined sidewall and a topmost end of the first inclined portion is in a range from 10 μm to 100 μm.

According to some embodiments of the present disclosure, an angle between the first inclined sidewall and a top surface of the substrate is in a range from 20 degrees to 70 degrees, and an angle between the second inclined sidewall and a top surface of the first protection layer is in a range from 20 degrees to 70 degrees.

According to some embodiments of the present disclosure, the first protection layer further covers a top surface of the periphery area of the substrate.

According to some embodiments of the present disclosure, the first metasurface layer includes a plurality of first pillars, and the plurality of first pillars stand on a top surface of the first protection layer and above the active area.

According to some embodiments of the present disclosure, a thickness of the first spacer layer is defined by a top surface of the substrate to a bottom surface of the first protection layer, and the thickness of the first spacer layer is in a range from 0.5 μm to 5 μm. A thickness of second spacer layer is defined by a top surface of the first protection layer to a bottom surface of the second protection layer, and the thickness of the second spacer layer is in a range from 0.5 μm to 5 μm.

According to some embodiments of the present disclosure, a refractive index of the first spacer layer is less than 1.7, a refractive index of the second spacer layer is less than 1.7, a refractive index difference between the first metasurface layer and the second spacer layer is greater than 0.7, and extinction coefficients of the first metasurface layer, the second spacer layer, and the first spacer layer at a wavelength between 400 nm and 700 nm are less than 0.1.

According to some embodiments of the present disclosure, an elastic modulus of the first spacer layer is in a range from 2 GPa to 10 GPa, and an elastic modulus of the second spacer layer is in a range from 2 GPa to 10 GPa.

According to some embodiments of the present disclosure, a coefficient of thermal expansion of the first spacer layer is in a range from 10 ppm/° C. to 300 ppm/° C., and a coefficient of thermal expansion of the second spacer layer is in a range from 10 ppm/° C. to 300 ppm/° C.

According to some embodiments of the present disclosure, a thickness of the first protection layer is in a range from 0.1 μm to 1 μm, and a thickness of the second protection layer is in a range from 0.1 μm to 1 μm.

According to some embodiments of the present disclosure, an elastic modulus of the first protection layer is in a range from 70 GPa to 400 GPa, and an elastic modulus of the second protection layer is in a range from 70 GPa to 400 GPa.

According to some embodiments of the present disclosure, the first metasurface layer includes a plurality of first pillars, a height of each of the first pillars is in a range from 0.5 μm to 1.2 μm, and a pitch between two of the first pillars is up to 0.8 μm.

According to some embodiments of the present disclosure, a material of the first metasurface layer includes Ta₂O₅, Nb₂O₅, TiO₂, ZrO₂, ZnO, titanium-doped tin oxide (TNO), or combinations thereof, wherein the titanium-doped tin oxide is a TiO₂-based transparent conductive oxide.

According to some embodiments of the present disclosure, a material of the first protection layer includes SiO₂, SiN, Nb₂O₅, Ta₂O₅, TiO₂, ZrO₂, ZnO, titanium-doped tin oxide (TNO) or combinations thereof, and a material of the second protection layer includes SiO₂, SiN, Nb₂O₅, Ta₂O₅, TiO₂, ZrO₂, ZnO, titanium-doped tin oxide (TNO) or combinations thereof.

According to some embodiments of the present disclosure, the image sensor further includes a third spacer layer and a third protection layer. The third spacer layer is disposed on the second protection layer. The third protection layer covers the third spacer layer. An elastic modulus ratio of the third protection layer to the third spacer layer is in a range from 30 to 200, and a thickness ratio of the third protection layer to the third spacer layer is in a range from 0.05 to 1.

According to some embodiments of the present disclosure, the image sensor further includes a second metasurface layer including a plurality of second pillars disposed on the second protection layer.

According to some embodiments of the present disclosure, the image sensor further includes a third spacer layer and a third protection layer. The third spacer layer is disposed between the first protection layer and the second spacer layer. The third protection layer is disposed between the first metasurface layer and the third spacer layer and covers the third spacer layer. An elastic modulus ratio of the third protection layer to the third spacer layer is in a range from 30 to 200, and a thickness ratio of the third protection layer to the third spacer layer is in a range from 0.05 to 1.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an enlargement view of a prior art image sensor.

FIG. 2 is a cross-sectional view of an image sensor in accordance with some embodiments of the present disclosure.

FIG. 3 is a cross-sectional view of an image sensor in accordance with some embodiments of the present disclosure.

FIG. 4 is a cross-sectional view of an image sensor in accordance with some embodiments of the present disclosure.

FIG. 5 is a cross-sectional view of an image sensor in accordance with some embodiments of the present disclosure.

FIG. 6 is a cross-sectional view of an image sensor having a single spacer layer with a 30° inclination angle in accordance with some simulation examples of the present disclosure.

FIG. 7 is a cross-sectional view of an image sensor having a single spacer layer with a 60° inclination angle in accordance with some simulation examples of the present disclosure.

FIG. 8 is a cross-sectional view of an image sensor having double spacer layers with 60° inclination angles in accordance with some simulation examples of the present disclosure.

FIG. 9 is a cross-sectional view of an image sensor having triple spacer layers with 60° inclination angles in accordance with some simulation examples of the present disclosure.

FIG. 10A to FIG. 10D are cross-sectional views at various stages for manufacturing the image sensor in FIG. 2.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

It will be understood that, although the terms “first,” “second,” etc. may be used herein to describe various elements, these elements should not be limited by these terms. These terms are only used to distinguish one element from another. For example, a “first element” may be termed a “second element,” and, similarly, a “second element” may be termed a “first element,” without departing from the scope of the embodiments. As used herein, the term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

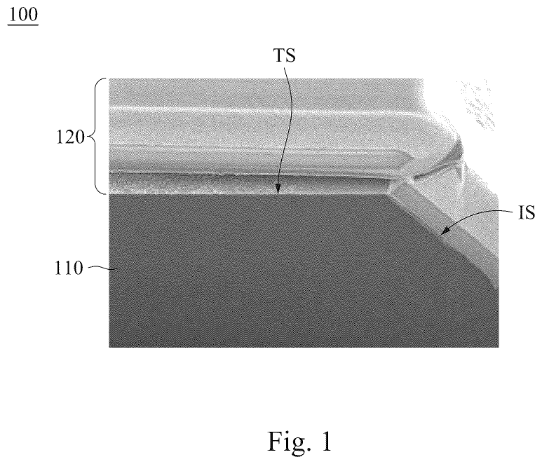

FIG. 1 is an enlargement view of a prior art image sensor 100. The prior art image sensor 100 includes a spacer layer 110 and a protection layer 120 conformally disposed on the spacer layer 110. As shown in FIG. 1, the spacer layer 110 has a top surface TS and an inclined sidewall IS connecting to the top surface TS. Since the materials of the spacer layer 110 and the protection layer 120 are different and a thickness ratio of the protection layer 120 to the spacer layer 110 is about 0.005, the stress of the protection layer 120 on the spacer layer 110 may be excessively concentrated around the bending edges between a top surface TS and an inclined sidewall IS of the spacer layer 110, resulting in failure (such as peeling or cracking) of the prior art image sensor 100, as shown in FIG. 1.

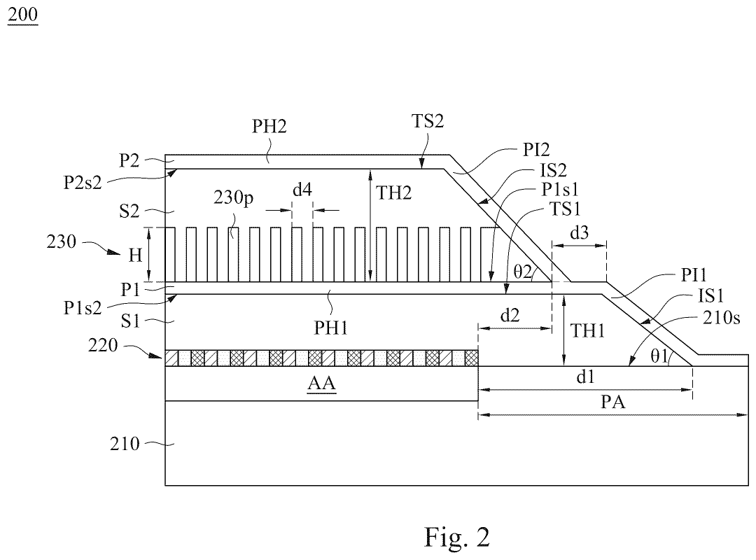

FIG. 2 is a cross-sectional view of an image sensor 200 in accordance with some embodiments of the present disclosure. The image sensor 200 includes a substrate 210, a color filter layer 220, a first spacer layer S1, a first protection layer P1, a first metasurface layer 230, a second spacer layer S2, and a second protection layer P2. The color filter layer 220 is disposed on the substrate 210. The first spacer layer S1 is disposed on the substrate 210 and covers the color filter layer 220. The first protection layer P1 covers the first spacer layer S1. The first metasurface layer 230 is disposed above the first protection layer P1. The second spacer layer S2 is disposed on the first protection layer P1 and covers the first metasurface layer 230. The second protection layer P2 covers the second spacer layer S2. Specifically, the first protection layer P1 is conformally disposed on the first spacer layer S1, and the second protection layer P2 is conformally disposed on the second spacer layer S2. The first protection layer P1 and the second protection layer P2 are also called sealing layers and are configured to encapsulate the image sensor 200. In other words, the first spacer layer S1 and the second spacer layer S2 do not expose the first protection layer P1 and the second protection layer P2. In some embodiments, the image sensor 200 is suitable for visible light applications.

In some embodiments, an elastic modulus ratio of the first protection layer P1 to the first spacer layer S1 is in a range from 30 to 200, such as 40, 50, 60, 70, 80, 90, 100, 110, 120, 130, 140, 150, 160, 170, 180, or 190. If the elastic modulus ratio was out of the above range, it may cause failure (such as peeling or cracking) around the bending edges between a first top surface TS1 and a first inclined sidewall IS1 of the first spacer layer S1 of the image sensor 200. In some embodiments, an elastic modulus ratio of the second protection layer P2 to the second spacer layer S2 is in a range from 30 to 200, such as 40, 50, 60, 70, 80, 90, 100, 110, 120, 130, 140, 150, 160, 170, 180, or 190. If the elastic modulus ratio was out of the above range, it may cause failure (such as peeling or cracking) around the bending edges between a second top surface TS2 and a second inclined sidewall IS2 of the second spacer layer S2 of the image sensor 200.

In some embodiments, a thickness ratio of the first protection layer P1 to the first spacer layer S1 is in a range from 0.05 to 1, such as 0.06, 0.07, 0.08, 0.09, 0.1, 0.2, 0.3, 0.4, 0.5, 0.6, 0.7, 0.8, or 0.9. If the thickness ratio was out of the above range, it may cause failure around the bending edges between the first top surface TS1 and the first inclined sidewall IS1 of the first spacer layer S1 of the image sensor 200, thereby decreasing the performance of the image sensor 200. In some embodiments, a thickness ratio of the second protection layer P2 to the second spacer layer S2 is in a range from 0.05 to 1, such as 0.06, 0.07, 0.08, 0.09, 0.1, 0.2, 0.3, 0.4, 0.5, 0.6, 0.7, 0.8, or 0.9. If the thickness ratio was out of the above range, it may cause failure around the bending edges between the second top surface TS2 and the second inclined sidewall IS2 of the second spacer layer S2 of the image sensor 200, thereby decreasing the performance of the image sensor 200.

Still referring to FIG. 2, the substrate 210 includes an active area AA and a periphery area PA adjacent to the active area AA, the active area AA includes a plurality of pixels (not shown), the color filter layer 220 is disposed on the pixels, and the first spacer layer S1 covers the active area AA and the periphery area PA of the substrate 210. In some embodiments, the substrate 210 may be a semiconductor substrate, an organic photoelectric conversion substrate, a semiconductor on insulator (SOI) substrate, or another suitable substrate.

It could be understood that the color filter layer 220 may include a plurality of color filters corresponding the plurality of pixels, in which each color filter corresponds to each pixel and each pixel corresponds to one photodiode (PD). In other embodiments, each pixel includes 2 PDs, 4 PDs, 9 PDs, but is not limited thereto. The active area AA of the substrate 210 is configured to sense light and generate an intensity signal according to the intensity of the light falling thereon. In some embodiments, the color filter layer 220 includes a plurality of red color filters, a plurality of green color filters, and a plurality of blue color filters, but is not limited thereto. In some embodiments, the first protection layer P1 further covers a top surface 210s of the periphery area PA of the substrate 210. In some embodiments, a thickness of the color filter layer 220 is in a range from 0.4 μm to 0.8 μm, such as 0.5, 0.6, or 0.7 μm.

As shown in FIG. 2, the first inclined sidewall IS1 of the first spacer layer S1 is above the periphery area PA of the substrate 210, and the second inclined sidewall IS2 of the second spacer layer S2 is above the periphery area PA of the substrate 210. A horizontal distance d1 between a bottommost end of the first inclined sidewall IS1 and an edge of the color filter layer 220 is greater than a horizontal distance d2 between a bottommost end of the second inclined sidewall IS2 and the edge of the color filter layer 220.

As shown in FIG. 2, the first protection layer P1 has a first horizontal portion PH1 and a first inclined portion PI1 connecting the first horizontal portion PH1 and covering the first inclined sidewall IS1 of the first spacer layer S1. The second protection layer P2 has a second horizontal portion PH2 and a second inclined portion PI2 connecting the second horizontal portion PH2 and covering the second inclined sidewall IS2 of the second spacer layer S2. In the embodiment of FIG. 1, the second inclined portion PI2 contacts the first horizontal portion PH1 such that the image sensor 200 has a continuous oblique surface.

In some embodiments, a horizontal distance d3 between the bottommost end of the second inclined sidewall IS2 and a topmost end of the first inclined portion PI1 is in a range from 10 μm to 100 μm, such as 20, 30, 40, 50, 60, 70, 80, or 90 μm. When the horizontal distance d3 is in the above range, the second protection layer P2 and the first protection layer P1 can provide a smooth oblique surface to avoid failure (such as peeling), thereby increasing the performance of the image sensor 200.

In some embodiments, an angle θ1 between the first inclined sidewall IS1 and the top surface 210s of the substrate 210 is in a range from 20 degrees to 70 degrees, such as 30, 40, 50, or 60 degrees. In some embodiments, an angle θ2 between the second inclined sidewall IS2 and a top surface P1s1 of the first protection layer P1 is in a range from 20 degrees to 70 degrees, such as 30, 40, 50, or 60 degrees. When the angle θ1 and the angle θ2 are in the above ranges, the second protection layer P2 and the first protection layer P1 can provide a smooth oblique surface to avoid failure (such as peeling), thereby increasing the performance of the image sensor 200. In the embodiment of FIG. 2, the angle θ1 and the angle θ2 are above the periphery area PA of the substrate 210.

In some embodiments, the first metasurface layer 230 includes a plurality of first pillars 230p, and the plurality of first pillars 230p stand on the top surface P1s1 of the first protection layer P1 and above the active area AA of the substrate 210, as shown in FIG. 2. Specifically, the first pillars 230p are above the color filter layer 220. More specifically, a portion of the second spacer layer S2 is filled in the space between two of the first pillars 230p.

In some embodiments, a height H of each first pillar 230p is in a range from 0.5 μm to 1.2 μm, such as 0.6, 0.8, 1, or 1.1 μm. If the height H was less than 0.5 μm, the phase modulation of the incident light may be insufficient and the first pillars 230p may fail to provide the necessary phase shifts needed for applications such as beam steering, focusing, or color separation. If the height H was greater than 1.2 μm, the stress on the first pillars 230p may be too large during the fabrication process, which may lead to defects such as cracking, delamination, or even peeling of the different material layers.

In some embodiments, a diameter of each first pillar 230p is in a range from 50 nm to 500 nm, such as 100, 150, 200, 250, 300, 350, 400, or 400 nm. When the diameter of each first pillar 230p is in the above range, the performance of the image sensor 200 can be increased.

In some embodiments, a pitch d4 between two of the first pillars 230p is up to 0.8 μm, such as 0.12, 0.2, 0.3, 0.4, 0.5, 0.6 or 0.75 μm. If the pitch d4 was greater than 0.8 μm, representing the more the portion of the second spacer layer S2 filled in the space between two of the first pillars 230p is, the more the mismatch of coefficient of thermal expansion (CTE) between different materials may occur, causing the thermal stress to be too high and failure of the image sensor.

In some embodiments, a material of the first metasurface layer 230 includes Ta₂O₅, Nb₂O₅, TiO₂, ZrO₂, ZnO, titanium-doped tin oxide (TNO), or combinations thereof. In some embodiments, the titanium-doped tin oxide is a TiO₂-based transparent conductive oxide.

In some embodiments, a coefficient of thermal expansion of the first spacer layer S1 is in a range from 10 ppm/° C. to 300 ppm/° C., such as 50, 100, 150, 200, or 250 ppm/° C. In some embodiments, a coefficient of thermal expansion of the second spacer layer S2 is in a range from 10 ppm/° C. to 300 ppm/° C., such as 50, 100, 150, 200, or 250 ppm/° C. When the coefficients of thermal expansion are in the above ranges, the performance of the image sensor 200 can be increased.

In some embodiments, a thickness TH1 of the first spacer layer S1 is defined by the top surface 210s of the substrate 210 to a bottom surface P1s2 of the first protection layer P1, and the thickness TH1 of the first spacer layer S1 is in a range from 0.5 μm to 5 μm, such as 0.6, 0.8, 1, 1.5, 2, 2.5, 3, 3.5, 4, or 4.5 μm. In some embodiments, a thickness TH2 of second spacer layer S2 is defined by the top surface P1s1 of the first protection layer P1 to a bottom surface P2s2 of the second protection layer P2, and the thickness TH2 of the second spacer layer S2 is in a range from 0.5 μm to 5 μm, such as 0.6, 0.8, 1, 1.5, 2, 2.5, 3, 3.5, 4, or 4.5 μm. When the thickness TH1 and the thickness TH2 are in the above ranges, the performance of the image sensor 200 can be increased.

In some embodiments, a refractive index of the first spacer layer S1 is less than 1.7. In some embodiments, a refractive index of the second spacer layer S2 is less than 1.7. In some embodiments, a refractive index difference between the first metasurface layer 230 and the second spacer layer S2 is greater than 0.7. When the refractive indices and the refractive index difference are in the above ranges, the performance of the image sensor 200 can be increased. In some embodiments, extinction coefficients of the first metasurface layer 230, the second spacer layer S2, and the first spacer layer S1 at a wavelength between 400 nm and 700 nm are less than 0.1. When the extinction coefficients are in the above ranges, the performance of the image sensor 200 can be increased.

In some embodiments, an elastic modulus of the first spacer layer S1 is in a range from 2 GPa to 10 GPa, such as 4, 6, or 8 GPa. In some embodiments, an elastic modulus of the second spacer layer S2 is in a range from 2 GPa to 10 GPa, such as 4, 6, or 8 GPa. When the elastic moduli are in the above ranges, the performance of the image sensor 200 can be increased.

In some embodiments, a thickness of the first protection layer P1 is in a range from 0.1 μm to 1 μm, such as 0.2, 0.5, or 0.7 μm. In some embodiments, a thickness of the second protection layer P2 is in a range from 0.1 μm to 1 μm, such as 0.2, 0.5, or 0.7 μm. When the thicknesses are in the above ranges, the performance of the image sensor 200 can be increased.

In some embodiments, an elastic modulus of the first protection layer P1 is in a range from 70 GPa to 400 GPa, such as 100, 150, 200, 250, 300, or 350 GPa. In some embodiments, an elastic modulus of the second protection layer is in a range from 70 GPa to 400 GPa, such as 100, 150, 200, 250, 300, or 350 GPa. When the elastic moduli are in the above ranges, the performance of the image sensor 200 can be increased.

In some embodiments, a material of the first protection layer P1 includes SiO₂, SiN, Nb₂O₅, Ta₂O₅, TiO₂, ZrO₂, ZnO, titanium-doped tin oxide (TNO) or combinations thereof. In some embodiments, a material of the second protection layer P2 includes SiO₂, SiN, Nb₂O₅, Ta₂O₅, TiO₂, ZrO₂, ZnO, titanium-doped tin oxide (TNO) or combinations thereof. In some embodiments, the material of the first protection layer P1 includes inorganic material, and the material of the second protection layer P2 includes inorganic material.

Referring to FIG. 1, the image sensor 200 has the smooth oblique surface formed by the second protection layer P2 and the first protection layer P1, so it can avoid failure (such as peeling or cracking) of the image sensor 200.

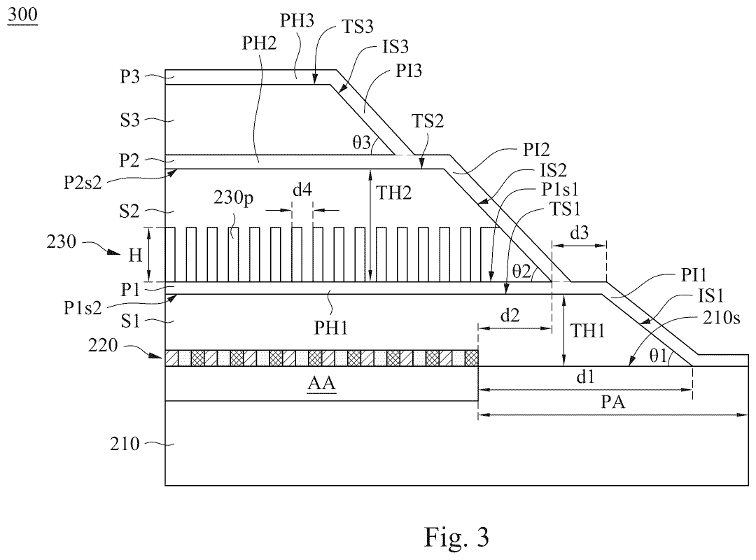

FIG. 3 is a cross-sectional view of an image sensor 300 in accordance with some embodiments of the present disclosure. The image sensor 300 in FIG. 3 is similar to the image sensor 200 in FIG. 2, except that the image sensor 300 further includes a third spacer layer S3 and a third protection layer P3. The third spacer layer S3 is disposed on the second protection layer P2. The third protection layer P3 covers the third spacer layer S3. Specifically, the third protection layer P3 is conformally disposed on the third spacer layer S3.

Still referring to FIG. 3, an angle θ3 between a third inclined sidewall IS3 and a second top surface TS2 is in a range from 20 degrees to 70 degrees, such as 30, 40, 50, or 60 degrees. When the angle θ3 is in the above range, the third protection layer P3 can provide a smooth oblique surface to avoid failure (such as peeling), thereby increasing the performance of the image sensor 300.

In some embodiments, an elastic modulus ratio of the third protection layer P3 to the third spacer layer S3 is in a range from 30 to 200, such as 40, 50, 60, 70, 80, 90, 100, 110, 120, 130, 140, 150, 160, 170, 180, or 190. In some embodiments, a thickness ratio of the third protection layer P3 to the third spacer layer S3 is in a range from 0.05 to 1, such as 0.06, 0.07, 0.08, 0.09, 0.1, 0.2, 0.3, 0.4, 0.5, 0.6, 0.7, 0.8, or 0.9. If the elastic modulus ratio and the thickness ratio were out of the above ranges, it may cause failure around the bending edges between a third top surface TS3 and the third inclined sidewall IS3 of the third spacer layer S3 of the image sensor 300, thereby decreasing the performance of the image sensor 300. Other features (such as the thickness, the coefficient of thermal expansion, the refractive index, the material, and so on) of the third spacer layer S3 and the third protection layer P3 may be the same as or similar to those of the first spacer layer S1 and the first protection layer P1, and the details thereof are not repeatedly described. The image sensor 300 also has the smooth oblique surface formed by the third protection layer P3, the second protection layer P2 and the first protection layer P1, so it can avoid failure (such as peeling or cracking) of the image sensor 300.

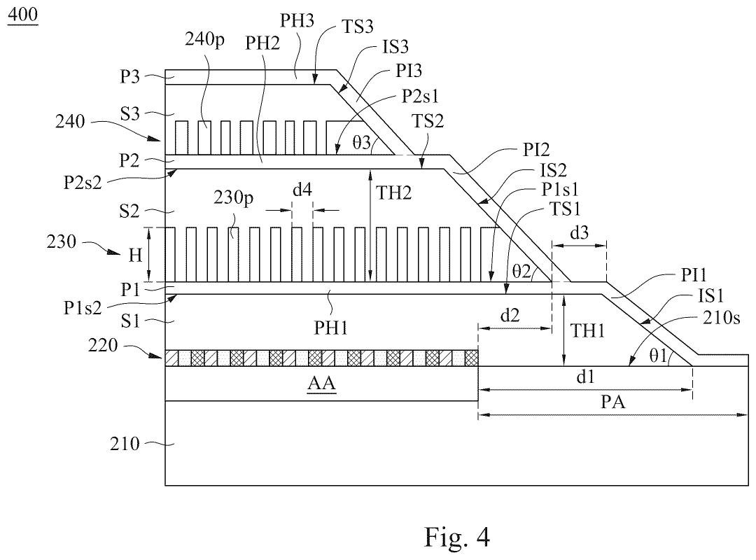

FIG. 4 is a cross-sectional view of an image sensor 400 in accordance with some embodiments of the present disclosure. The image sensor 400 in FIG. 4 is similar to the image sensor 300 in FIG. 3, except that the image sensor 400 further includes a second metasurface layer 240 including a plurality of second pillars 240p disposed on the second protection layer P2. Specifically, the plurality of second pillars 240p stand on a top surface P2s1 of the second protection layer P2 and above the active area AA of the substrate 210. More specifically, a portion of the third spacer layer S3 is filled in the space between two of the second pillars 240p. Other features (such as the height, the pitch, the material, and so on) of the second metasurface layer 240 may be the same as or similar to those of the first metasurface layer 230, and the details thereof are not repeatedly described. The image sensor 400 also has the smooth oblique surface formed by the third protection layer P3, the second protection layer P2 and the first protection layer P1, so it can avoid failure (such as peeling or cracking) of the image sensor 400.

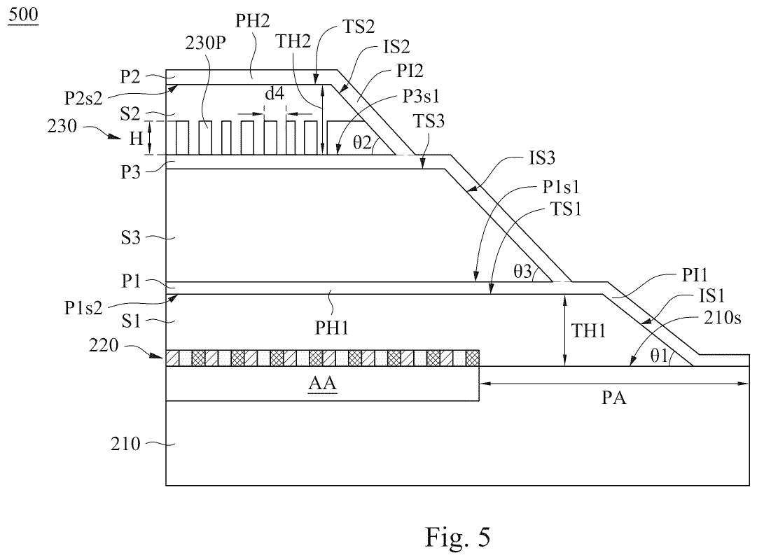

FIG. 5 is a cross-sectional view of an image sensor 500 in accordance with some embodiments of the present disclosure. The image sensor 500 in FIG. 5 is similar to the image sensor 200 in FIG. 2, except that the image sensor 500 further includes a third spacer layer S3 and a third protection layer P3. The third spacer layer S3 is disposed between the first protection layer P1 and the second spacer layer S2. The third protection layer P3 is disposed between the first metasurface layer 230 and the third spacer layer S3 and covers the third spacer layer S3. More specifically, the plurality of first pillars 230p of the first metasurface layer 230 stand on a top surface P3s1 of the third protection layer P3. In the embodiment of FIG. 5, the third protection layer P3 is conformally disposed on the third spacer layer S3.

In some embodiments, an elastic modulus ratio of the third protection layer P3 to the third spacer layer S3 is in a range from 30 to 200, and a thickness ratio of the third protection layer P3 to the third spacer layer S3 is in a range from 0.05 to 1. If the elastic modulus ratio and the thickness ratio were out of the above ranges, it may cause failure around the bending edges between a third top surface TS3 and the third inclined sidewall IS3 of the third spacer layer S3 of the image sensor 500, thereby decreasing the performance of the image sensor 500. Other features (such as the thickness, the coefficient of thermal expansion, the refractive index, the material, and so on) of the third spacer layer S3 and the third protection layer P3 may be the same as or similar to those of the first spacer layer S1 and the first protection layer P1, and the details thereof are not repeatedly described. The image sensor 500 also has the smooth oblique surface formed by the second protection layer P2, the third protection layer P3 and the first protection layer P1, so it can avoid failure (such as peeling or cracking) of the image sensor 500.

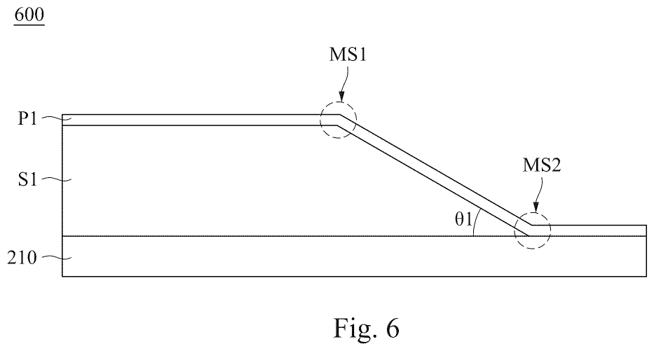

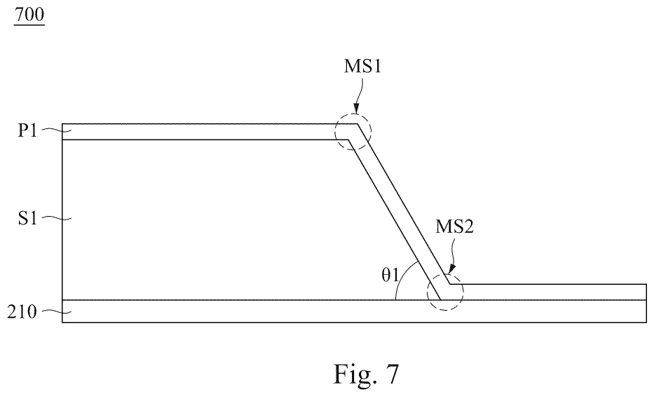

FIG. 6 is a cross-sectional view of an image sensor 600 having a single spacer layer with a 30° inclination angle (i.e., the angle θ1 of the first spacer layer S1 is) 30° in accordance with some simulation examples of the present disclosure. FIG. 7 is a cross-sectional view of an image sensor 700 having a single spacer layer with a 60° inclination angle (i.e., the angle θ1 of the first spacer layer S1 is) 60° in accordance with some simulation examples of the present disclosure. The image sensors 600 and 700 were designed to simulate the stress of the first protection layer P1 on the first spacer layer S1, in which the maximum stress is commonly around the bending edges of the first protection layer P1, as the arrows (maximum stress MS1 and MS2) shown in FIG. 6 and FIG. 7.

Table 1 below shows specific parameters and the results of Experimental Examples 1 to 8 and Comparative Example 1. It could be understood that Experimental Examples 1, 3, 5, and 7 correspond to the image sensor 600 in FIG. 6, and Experimental Examples 2, 4, 6, and 8 and Comparative Example 1 correspond to the image sensor 700 in FIG. 7. It could be understood that the “stress” in Table 1 represents one of the maximum stress MS1 or MS2, which merely shows the maximum stress value.

TABLE 1

| | | Thickness | Thickness | Thickness | |
|---|---|---|---|---|---|
| | | of P1 | of S1 | ratio of | Stress |
| | Angle θ1 | [μm] | [μm] | P1/S1 | [MPa] |
| Experimental | 30° | 0.1 | 1 | 0.1 | 726 |
| Example 1 | | | | | |
| Experimental | 60° | 0.1 | 1 | 0.1 | 1150 |
| Example 2 | | | | | |
| Experimental | 30° | 1 | 1 | 1 | 333 |
| Example 3 | | | | | |
| Experimental | 60° | 1 | 1 | 1 | 447 |
| Example 4 | | | | | |
| Experimental | 30° | 0.1 | 2 | 0.05 | 950 |
| Example 5 | | | | | |
| Experimental | 60° | 0.1 | 2 | 0.05 | 1583 |
| Example 6 | | | | | |
| Experimental | 30° | 1 | 2 | 0.5 | 438 |
| Example 7 | | | | | |
| Experimental | 60° | 1 | 2 | 0.5 | 620 |
| Example 8 | | | | | |
| Comparative | 60° | 0.01 | 2 | 0.005 | 2198 |
| Example 1 | | | | | |

Referring to Table 1, because the thickness ratio of the first protection layer P1 to the first spacer layer S1 in Comparative Example 1 is less than 0.05, the stress is greater than those in Experimental Examples 1 to 8.

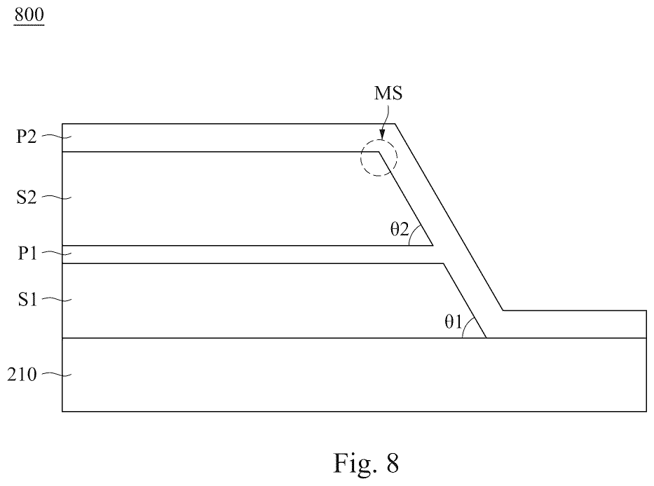

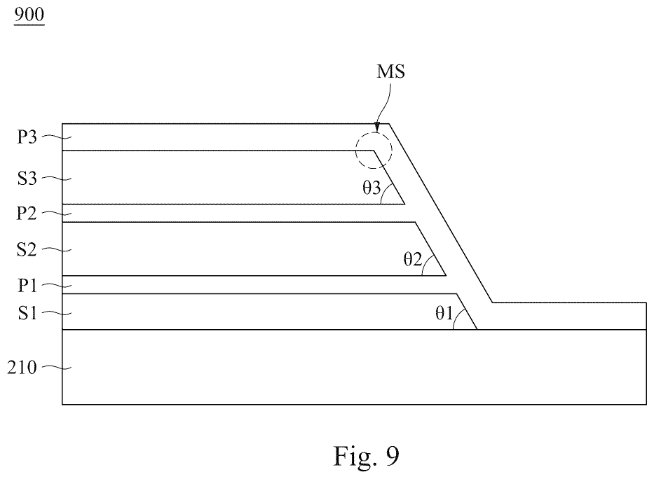

FIG. 8 is a cross-sectional view of an image sensor 800 having double spacer layers with 60° inclination angles in accordance with some simulation examples of the present disclosure. FIG. 9 is a cross-sectional view of an image sensor 900 having triple spacer layers with 60° inclination angles in accordance with some simulation examples of the present disclosure. The image sensors 800 and 900 were designed to simulate the stress of the protection layer on the spacer layer, in which the maximum stress is commonly around the bending edges of the protection layer, as the arrows (maximum stress MS) shown in FIG. 8 and FIG. 9.

Table 2 below shows specific parameters and the results of Experimental Examples 9 to 10 and Comparative Examples 2 to 3. It could be understood that Experimental Example 9 and Comparative Example 2 correspond to the image sensor 800 in FIG. 8, and Experimental Example 10 and Comparative Example 3 correspond to the image sensor 900 in FIG. 9. It could be understood the “stress” in Table 2 represents the maximum stress value of the maximum stress MS1, or MS2.

TABLE 2

| | Layers of | Thickness | |
|---|---|---|---|
| | protection layer | ratio of | |
| | Angle θ1, θ2, | P1/S1, P2/S2, | Stress |
| | and θ3 | and P3/S3 | [MPa] |
| Experimental | Double layers | 0.05~0.5 | 1909 |
| Example 9 | 60° | | |
| Comparative | Double layers | <0.05 | 2237 |
| Example 2 | 60° | | |
| Experimental | Triple layers | 0.05~0.5 | 1732 |
| Example 10 | 60° | | |
| Comparative | Triple layers | <0.05 | 2037 |
| Example 3 | 60° | | |

Referring to Table 2, because the thickness ratio of the first protection layer P1 to the first spacer layer S1 and the thickness ratio of the second protection layer P2 to the second spacer layer S2 (and/or the thickness ratio of the third protection layer P3 to the third spacer layer S3) in Comparative Examples 2 and 3 are less than 0.05, the stress are greater than those in Experimental Examples 9 and 10.

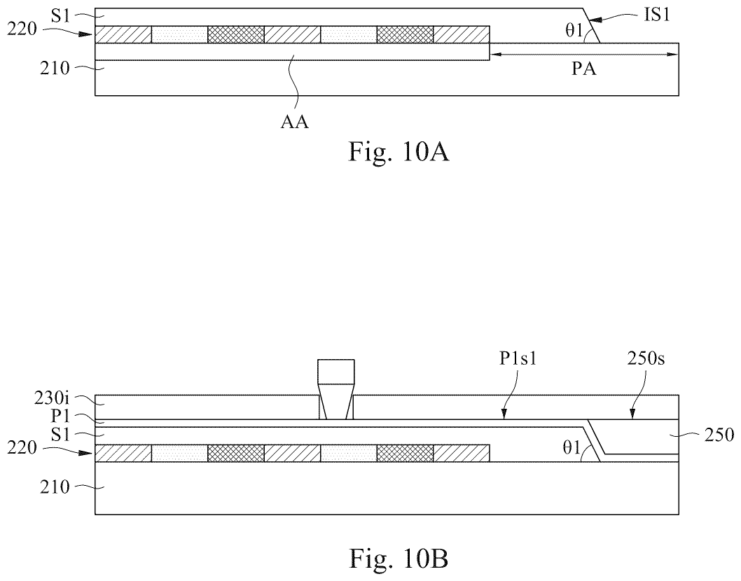

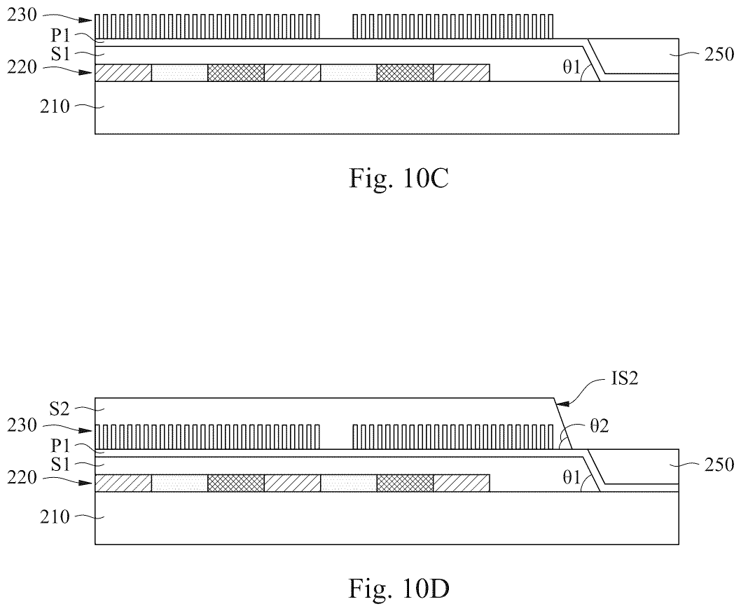

FIG. 10A to FIG. 10D are cross-sectional views at various stages for manufacturing the image sensor 200 in FIG. 2. Referring to FIG. 10A, the substrate 210 is provided. The color filter layer 220 is formed on the active area AA of the substrate 210. The material of the first spacer layer S1 is formed on the substrate 210 and the color filter layer 220, and then a lithography and etching process is performed on the first spacer layer S1 so that the first spacer layer S1 having the angle θ1 and the first inclined sidewall IS1 is formed.

Referring to FIG. 10A and FIG. 10B, the first protection layer P1 is formed on the first spacer layer S1 and the substrate 210. A refill layer 250 is formed around the first inclined sidewall IS1 of the first spacer layer S1. In some embodiments, the top surface P1s1 of the first protection layer P1 is substantially coplanar with a top surface 250s of the refill layer 250. After the refill layer 250 is formed, a metasurface material 230i is formed on the first protection layer P1 and the refill layer 250.

Referring to FIG. 10B and FIG. 10C, a patterning process is performed on the metasurface material 230i to form the first metasurface layer 230.

Referring to FIG. 10C and FIG. 10D, the material of the second spacer layer S2 is formed on the first protection layer P1 and the first metasurface layer 230, and then a lithography and etching process is performed on the second spacer layer S2 so that the second spacer layer S2 having the angle θ2 and the second inclined sidewall IS2 is formed.

Referring to FIG. 10D and FIG. 2, the refill layer 250 is removed, and then the second protection layer P2 is formed on the second spacer layer S2, thereby forming the image sensor 200.

In summary, the image sensors of the present disclosure have specific elastic modulus ratios and thickness ratios between different layers, which can optimize the stress between different layers in the image sensors to avoid failure (such as peeling or cracking), thereby increasing the image sensors' performance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a substrate;
a color filter layer disposed on the substrate;
a first spacer layer disposed on the substrate and covering the color filter layer;
a first protection layer covering the first spacer layer;
a first metasurface layer disposed above the first protection layer;
a second spacer layer disposed on the first protection layer and covering the first metasurface layer; and
a second protection layer covering the second spacer layer, wherein an elastic modulus ratio of the first protection layer to the first spacer layer is in a range from 30 to 200, an elastic modulus ratio of the second protection layer to the second spacer layer is in a range from 30 to 200, a thickness ratio of the first protection layer to the first spacer layer is in a range from 0.05 to 1, and a thickness ratio of the second protection layer to the second spacer layer is in a range from 0.05 to 1.

2. The image sensor of claim 1, wherein the substrate comprises an active area and a periphery area adjacent to the active area, the active area comprises a plurality of pixels, the color filter layer is disposed on the pixels, and the first spacer layer covers the active area and the periphery area.

3. The image sensor of claim 2, wherein the first spacer layer has a first inclined sidewall above the periphery area, and the second spacer layer has a second inclined sidewall above the periphery area, and
wherein a horizontal distance between a bottommost end of the first inclined sidewall and an edge of the color filter layer is greater than a horizontal distance between a bottommost end of the second inclined sidewall and the edge of the color filter layer.

4. The image sensor of claim 3, wherein the first protection layer has a first horizontal portion and a first inclined portion connecting the first horizontal portion and covering the first inclined sidewall,
wherein the second protection layer has a second horizontal portion and a second inclined portion connecting the second horizontal portion and covering the second inclined sidewall, and
wherein the second inclined portion contacts the first horizontal portion such that the image sensor has a continuous oblique surface.

5. The image sensor of claim 4, wherein a horizontal distance between the bottommost end of the second inclined sidewall and a topmost end of the first inclined portion is in a range from 10 μm to 100 μm.

6. The image sensor of claim 3, wherein an angle between the first inclined sidewall and a top surface of the substrate is in a range from 20 degrees to 70 degrees, and an angle between the second inclined sidewall and a top surface of the first protection layer is in a range from 20 degrees to 70 degrees.

7. The image sensor of claim 2, wherein the first protection layer further covers a top surface of the periphery area of the substrate.

8. The image sensor of claim 2, wherein the first metasurface layer comprises a plurality of first pillars, and the plurality of first pillars stand on a top surface of the first protection layer and above the active area.

9. The image sensor of claim 1, wherein a thickness of the first spacer layer is defined by a top surface of the substrate to a bottom surface of the first protection layer, and the thickness of the first spacer layer is in a range from 0.5 μm to 5 μm, and
wherein a thickness of second spacer layer is defined by a top surface of the first protection layer to a bottom surface of the second protection layer, and the thickness of the second spacer layer is in a range from 0.5 μm to 5 μm.

10. The image sensor of claim 1, wherein a refractive index of the first spacer layer is less than 1.7, a refractive index of the second spacer layer is less than 1.7, a refractive index difference between the first metasurface layer and the second spacer layer is greater than 0.7, and extinction coefficients of the first metasurface layer, the second spacer layer, and the first spacer layer at a wavelength between 400 nm and 700 nm are less than 0.1.

11. The image sensor of claim 1, wherein an elastic modulus of the first spacer layer is in a range from 2 GPa to 10 GPa, and an elastic modulus of the second spacer layer is in a range from 2 GPa to 10 GPa.

12. The image sensor of claim 1, wherein a coefficient of thermal expansion of the first spacer layer is in a range from 10 ppm/° C. to 300 ppm/° C., and a coefficient of thermal expansion of the second spacer layer is in a range from 10 ppm/° C. to 300 ppm/° C.

13. The image sensor of claim 1, wherein a thickness of the first protection layer is in a range from 0.1 μm to 1 μm, and a thickness of the second protection layer is in a range from 0.1 μm to 1 μm.

14. The image sensor of claim 1, wherein an elastic modulus of the first protection layer is in a range from 70 GPa to 400 GPa, and an elastic modulus of the second protection layer is in a range from 70 GPa to 400 GPa.

15. The image sensor of claim 1, wherein the first metasurface layer comprises a plurality of first pillars, a height of each of the first pillars is in a range from 0.5 μm to 1.2 μm, a diameter of each of the first pillars is in a range from 50 nm to 500 nm, and a pitch between two of the first pillars is up to 0.8 μm.

16. The image sensor of claim 1, wherein a material of the first metasurface layer comprises Ta₂O₅, Nb₂O₅, TiO₂, ZrO₂, ZnO, titanium-doped tin oxide (TNO), or combinations thereof, wherein the titanium-doped tin oxide is a TiO₂-based transparent conductive oxide.

17. The image sensor of claim 1, wherein a material of the first protection layer comprises SiO₂, SiN, Nb₂O₅, Ta₂O₅, TiO₂, ZrO₂, ZnO, titanium-doped tin oxide (TNO) or combinations thereof, and a material of the second protection layer comprises SiO₂, SiN, Nb₂O₅, Ta₂O₅, TiO₂, ZrO₂, ZnO, titanium-doped tin oxide (TNO) or combinations thereof.

18. The image sensor of claim 1, further comprising:
a third spacer layer disposed on the second protection layer; and
a third protection layer covering the third spacer layer, wherein an elastic modulus ratio of the third protection layer to the third spacer layer is in a range from 30 to 200, and a thickness ratio of the third protection layer to the third spacer layer is in a range from 0.05 to 1.

19. The image sensor of claim 18, further comprising:
a second metasurface layer comprising a plurality of second pillars disposed on the second protection layer.

20. The image sensor of claim 1, further comprising:
a third spacer layer disposed between the first protection layer and the second spacer layer; and
a third protection layer disposed between the first metasurface layer and the third spacer layer and covering the third spacer layer, wherein an elastic modulus ratio of the third protection layer to the third spacer layer is in a range from 30 to 200, and a thickness ratio of the third protection layer to the third spacer layer is in a range from 0.05 to 1.
